(19) United States
(12) Patent Application Publication
(10) Pub. No.: US 2020/0411322 A1
(43) Pub. Date: Dec. 31, 2020

(54) APPARATUS AND METHOD FOR TREATING SUBSTRATE

(71) Applicant: SEMES CO., LTD., Cheonan-si (KR)

(72) Inventors: Seong Soo LEE, Cheonan-si (KR); Junkeon AHN, Sejong-si (KR); Junghwan LEE, Pyeongtaek-si (KR); Ohyeol KWON, Cheonan-si (KR); Soo Young PARK, Incheon (KR)

(73) Assignee: SEMES CO., LTD., Cheonan-si (KR)

(21) Appl. No.: 16/913,024

(22) Filed: Jun. 26, 2020

(30) Foreign Application Priority Data
Jun. 27, 2019 (KR) 10-2019-0077271

(51) Int. Cl. H01L 21/268; H01L 21/683; H01L 21/67

(52) U.S. Cl. CPC H01L 21/268; H01L 21/6715; H01L 21/683

(57) ABSTRACT

An apparatus for treating a substrate includes a housing having a treatment space therein, a support unit that supports the substrate in the housing, a liquid dispensing unit that dispenses a liquid onto the substrate supported on the support unit, a laser irradiation unit that irradiates a laser to an edge region of the substrate, and a controller that controls the liquid dispensing unit and the laser irradiation unit. The laser irradiation unit includes a plate provided on the liquid so as to be brought into contact with a surface of the liquid dispensed onto the substrate and a laser irradiation member that irradiates the laser to the edge region of the substrate, which is supported on the support unit, through the plate.

### CROSS-REFERENCE TO RELATED APPLICATIONS

A claim for priority under 35 U.S.C. § 119 is made to Korean Patent Application No. 10-2019-0077271 filed on Jun. 27, 2019, in the Korean Intellectual Property Office, the entire contents of which are hereby incorporated by reference.

### BACKGROUND

Embodiments of the inventive concept described herein relate to an apparatus and method for treating a substrate, and more particularly, relate to an apparatus and method for treating a substrate by dispensing a liquid onto the substrate and irradiating a laser to the substrate.

A process of manufacturing an integrated circuit element such as a semiconductor element or a flat panel display element includes a process of removing a film on a substrate by irradiating a laser beam to the substrate. However, particles are generated in the laser beam irradiation process. Due to high-density, high-integration, and high-performance of the semiconductor element, scaling-down of a circuit pattern rapidly proceeds. Therefore, contaminants such as particles remaining on the surface of the substrate greatly affect the characteristics and yield of the semiconductor element.

Accordingly, as illustrated in FIG. 1, when a substrate W is treated by using a laser L, a suction device 5 for suctioning dust is used to remove particles P.

However, in a process of removing a thin film T on the surface of the substrate W by irradiating the laser L to the substrate W, the particles P on the substrate W are separated from the substrate W and are suctioned by the suction device 5, but some particles or small-sized fine particles adhere to the substrate W again without being suctioned by the suction device 5.

Furthermore, in a case where, as illustrated in FIG. 2, the laser L is irradiated to the substrate W while a liquid is dispensed onto the surface of the substrate W, a liquid film on the substrate W has a corrugated surface, and therefore the surface of the liquid film on the substrate W is not even. When the laser L is irradiated to the surface of the liquid film, the laser L is refracted, and due to this, the laser L is not irradiated to a desired position on the substrate W.

Moreover, because the laser L is irradiated in a direction perpendicular to the substrate W from above the substrate W, a space for providing an irradiation path of the laser L is required above the substrate W. Due to this, the volume of a treatment space of a substrate treating apparatus is increased.

### SUMMARY

Embodiments of the inventive concept provide a substrate treating apparatus and method for efficiently treating a substrate.

Furthermore, embodiments of the inventive concept provide a substrate treating apparatus and method for minimizing attachment of impurities to a substrate in a process of treating the substrate by irradiating a laser to the substrate.

In addition, embodiments of the inventive concept provide a substrate treating apparatus and method for allowing a laser to accurately reach a desired region on a substrate when the laser is irradiated to the substrate having a liquid layer thereon.

The technical problems to be solved by the inventive concept are not limited to the aforementioned problems, and any other technical problems not mentioned herein will be clearly understood from the following description by those skilled in the art to which the inventive concept pertains.

According to an exemplary embodiment, an apparatus for treating a substrate includes a housing having a treatment space therein, a support unit that supports the substrate in the housing, a liquid dispensing unit that dispenses a liquid onto the substrate supported on the support unit, a laser irradiation unit that irradiates a laser to an edge region of the substrate, and a controller that controls the liquid dispensing unit and the laser irradiation unit. The laser irradiation unit includes a plate provided on the liquid so as to be brought into contact with a surface of the liquid dispensed onto the substrate and a laser irradiation member that irradiates the laser to the edge region of the substrate, which is supported on the support unit, through the plate.

According to an embodiment, an upper surface of the plate may be parallel to the substrate placed on the support unit.

According to an embodiment, an upper surface of the plate may be rounded.

According to an embodiment, the upper surface of the plate may be convex.

According to an embodiment, an upper surface of the plate may be inclined along a radial direction of the substrate placed on the support unit.

According to an embodiment, the upper surface of the plate may be upwardly inclined in a direction toward the center of the substrate placed on the support unit.

According to an embodiment, the laser irradiation member may irradiate the laser in a direction perpendicular to the substrate placed on the support unit.

According to an embodiment, on a side of the substrate placed on the support unit, the laser irradiation member may irradiate the laser to the plate in a direction parallel to the substrate.

According to an embodiment, the laser irradiation member may include a light source and an optical-path changing member including a mirror that changes a path of light irradiated by the light source, and the optical-path changing member may further include a mirror actuator that moves the mirror.

According to an embodiment, the controller may control the mirror actuator to change a position of the mirror such that a position in which the laser is irradiated to the substrate is changed while the laser is irradiated.

According to an embodiment, the laser irradiation member may include a plate actuator that moves the plate, and the controller may control the plate actuator to change a position of the plate to correspond to an irradiation position of the laser such that the laser is irradiated to a specific position of the plate while the irradiation position of the laser is changed.

According to an embodiment, the controller may control the laser irradiation member such that an irradiation position of the laser in which the laser is irradiated to the plate is changed along a radial direction of the substrate placed on the support unit.

According to an embodiment, the controller may control the laser irradiation member such that an irradiation position of the laser in which the laser is irradiated to the plate is changed along an up-down direction.

According to an embodiment, the controller may control the liquid dispensing unit and the laser irradiation unit such that the liquid is dispensed and the laser is irradiated in a state in which the plate is brought into contact with the liquid.

According to an exemplary embodiment, an apparatus for treating a substrate includes a housing having a treatment space therein, a support unit that supports the substrate in the housing, a liquid dispensing unit that dispenses a liquid onto the substrate supported on the support unit, and a laser irradiation unit that irradiates a laser to the substrate. The laser irradiation unit includes a plate provided on the liquid so as to be brought into contact with a surface of the liquid dispensed onto the substrate and a laser irradiation member that irradiates the laser to the substrate, which is supported on the support unit, through the plate.

According to an embodiment, an upper surface of the plate may be parallel to the substrate placed on the support unit.

According to an embodiment, an upper surface of the plate may be convex.

According to an embodiment, an upper surface of the plate may be upwardly inclined in a direction toward the center of the substrate placed on the support unit.

According to an embodiment, the laser irradiation member may include a light source and an optical-path changing member including a mirror that changes a path of light irradiated by the light source, and the optical-path changing member may further include a mirror actuator that moves the mirror.

According to an embodiment, the apparatus may further include a controller that controls the liquid dispensing unit and the laser irradiation unit, and the controller may control the mirror actuator to change a position of the mirror such that a position in which the laser is irradiated to the substrate is changed while the laser is irradiated.

According to an exemplary embodiment, a method for treating a substrate includes forming a liquid film on the substrate by dispensing a liquid onto the substrate and treating the substrate by irradiating a laser to the substrate, in which a plate is brought into contact with the liquid film formed on the substrate, and the laser transmits through the plate to treat the substrate.

According to an embodiment, the treating of the substrate may be a process of removing a thin film on the substrate by using the laser.

According to an embodiment, the thin film on the substrate may be a thin film provided on an edge region of the substrate.

According to an embodiment, an upper surface of the plate may be provided parallel to the substrate placed on a support unit, and the laser may be irradiated to the plate in a direction perpendicular to the substrate.

According to an embodiment, an upper surface of the plate may be inclined toward the center of the substrate along a radial direction of the substrate, and the laser may be irradiated to an inclined surface of the plate from outside the substrate.

According to an embodiment, an upper surface of the plate may be convex such that the laser is irradiated to a set position on the substrate, and the laser may be irradiated to a convex portion.

According to an embodiment, during a process, a position of the plate may be fixed, and an irradiation position of the laser may be changed along a radial direction of the substrate.

According to an embodiment, during a process, a position of the plate may be fixed, and an irradiation position of the laser irradiated to the plate may be changed along an up-down direction.

According to an embodiment, an irradiation position of the laser may be changed along a radial direction of the substrate, and a position of the plate, together with the irradiation position of the laser, may be changed such that the laser is irradiated to the same point on the plate.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a schematic view illustrating a general process of treating a substrate by irradiating a laser to the substrate;

FIG. 2 is a schematic view illustrating a problem encountered when a laser is irradiated in a state in which a liquid film is formed on a substrate;

FIG. 3 is a plan view illustrating a substrate treating apparatus according to an embodiment of the inventive concept;

FIG. 4 is a schematic sectional view illustrating a chamber for treating a substrate by irradiating a laser in the substrate treating apparatus of FIG. 3;

FIGS. 5 to 10 illustrate a process of irradiating a laser to a substrate in a film removal process according to an embodiment of the inventive concept; and

FIGS. 11 to 14 illustrate other embodiments of the inventive concept.

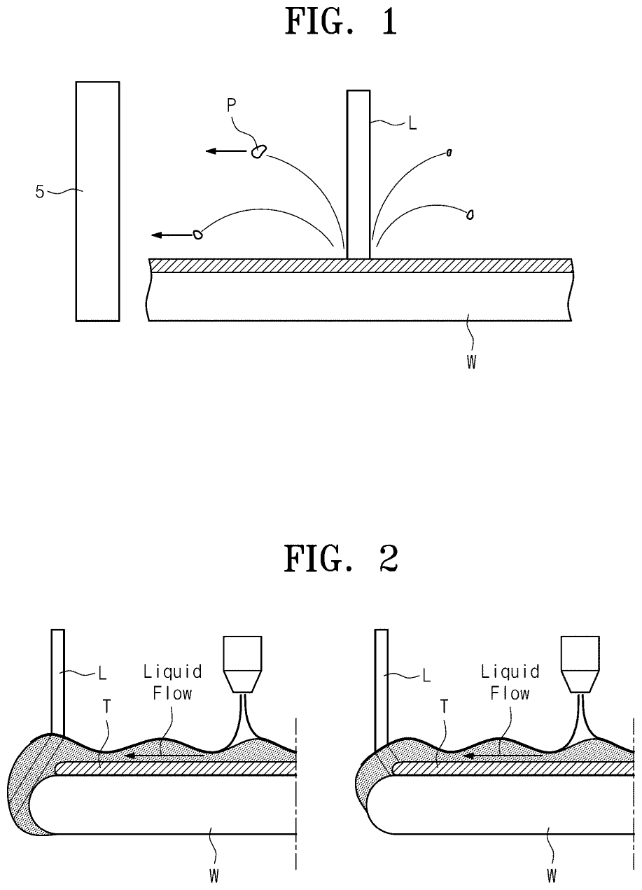

### DETAILED DESCRIPTION

Hereinafter, embodiments of the inventive concept will be described in detail with reference to the accompanying drawings such that those skilled in the art to which the inventive concept pertains can readily carry out the inventive concept. However, the inventive concept may be implemented in various different forms and is not limited to the embodiments described herein. Furthermore, in describing the embodiments of the inventive concept, detailed descriptions related to well-known functions or configurations will be omitted when they may make subject matters of the inventive concept unnecessarily obscure. In addition, components performing similar functions and operations are provided with identical reference numerals throughout the accompanying drawings.

The terms “include” and “comprise” in the specification are “open type” expressions just to say that the corresponding components exist and, unless specifically described to the contrary, do not exclude but may include additional components. Specifically, it should be understood that the terms “include”, “comprise”, and “have”, when used herein, specify the presence of stated features, integers, steps, operations, components, and/or parts, but do not preclude the presence or addition of one or more other features, integers, steps, operations, components, parts, and/or groups thereof.

The terms of a singular form may include plural forms unless otherwise specified. Furthermore, in the drawings, the shapes and dimensions of components may be exaggerated for clarity of illustration.

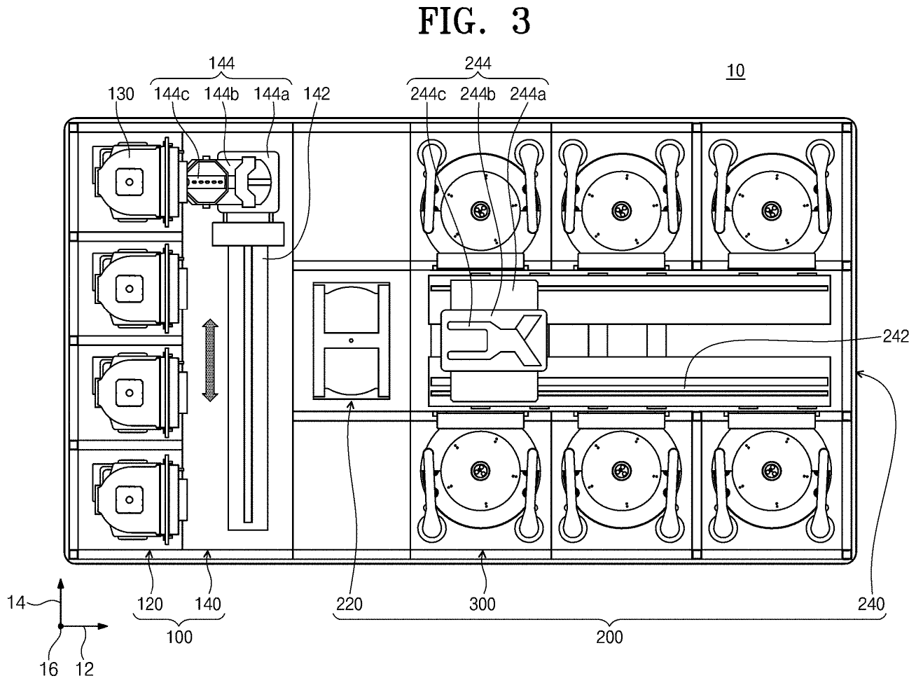

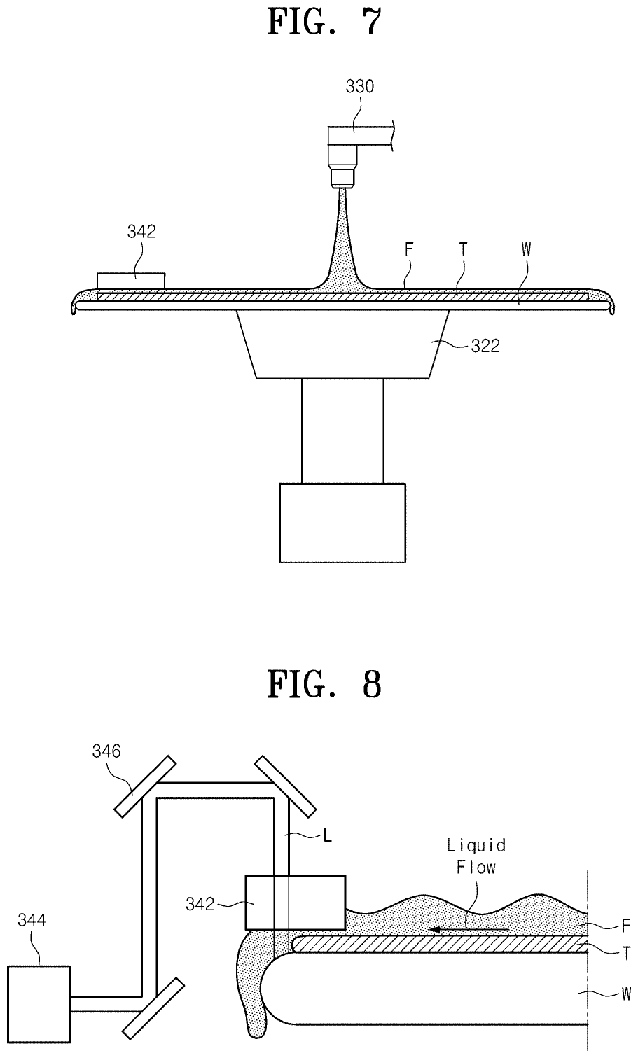

Hereinafter, embodiments of the inventive concept will be described in detail with reference to FIGS. 3 to 14.

Referring to FIG. 3, a substrate treating apparatus 10 has an index module 100 and a process module 200. The index module 100 has a load port 120 and a transfer frame 140. The load port 120, the transfer frame 140, and the process module 200 are sequentially arranged in a row. Hereinafter, a direction in which the load port 120, the transfer frame 140, and the process module 200 are arranged is referred to as a first direction 12, a direction perpendicular to the first direction 12 when viewed from above is referred to as a second direction 14, and a direction perpendicular to the plane including the first direction 12 and the second direction 14 is referred to as a third direction 16.

A carrier 130 having substrates W received therein is seated on the load port 120. A plurality of load ports 120 are provided. The load ports 120 are disposed in a row along the second direction 14. The number of load ports 120 may be increased or decreased depending on process efficiency and footprint conditions of the process module 200. The carrier 130 has a plurality of slots (not illustrated) formed therein in which the substrates W are received in horizontal positions relative to the ground. A front opening unified pod (FOUP) may be used as the carrier 130.

The process module 200 has a buffer unit 220, a transfer chamber 240, and process chambers 300. The transfer chamber 240 is disposed such that the lengthwise direction thereof is parallel to the first direction 12. The process chambers 300 are disposed on opposite sides of the transfer chamber 240. On the opposite sides of the transfer chamber 240, the process chambers 300 are provided to be symmetric to each other with respect to the transfer chamber 240. A plurality of process chambers 300 are provided on one side of the transfer chamber 240. Some of the process chambers 300 are disposed along the lengthwise direction of the transfer chamber 240. Furthermore, other process chambers 300 are stacked one above another.

In other words, the process chambers 300 on the one side of the transfer chamber 240 may be disposed in an A×B array. Here, “A” denotes the number of process chambers 300 provided in a row along the first direction 12, and “B” denotes the number of process chambers 300 provided in a column along the third direction 16. In a case where four or six process chambers 300 are provided on the one side of the transfer chamber 240, the process chambers 300 may be disposed in a 2×2 or 3×2 array. The number of process chambers 300 may be increased or decreased. Alternatively, the process chambers 300 may be provided on only the one side of the transfer chamber 240. In another case, the process chambers 300 may be provided in a single layer on the opposite sides of the transfer chamber 240.

The buffer unit 220 is disposed between the transfer frame 140 and the transfer chamber 240. The buffer unit 220 provides a space in which the substrates W stay before transferred between the transfer chamber 240 and the transfer frame 140. The buffer unit 220 has slots (not illustrated) formed therein in which the substrates W are placed. The slots (not illustrated) are spaced apart from each other along the third direction 16. The buffer unit 220 is open at one side facing the transfer frame 140 and at an opposite side facing the transfer chamber 240.

The transfer frame 140 transfers the substrates W between the carriers 130 seated on the load ports 120 and the buffer unit 220. An index rail 142 and an index robot 144 are provided in the transfer frame 140. The index rail 142 is disposed such that the lengthwise direction thereof is parallel to the second direction 14. The index robot 144 is installed on the index rail 142 and rectilinearly moves along the index rail 142 in the second direction 14. The index robot 144 has a base 144a, a body 144b, and an index arm 144c. The base 144a is installed so as to be movable along the index rail 142. The body 144b is coupled to the base 144a. The body 144b is movable on the base 144a along the third direction 16. Furthermore, the body 144b is rotatable on the base 144a. The index arm 144c is coupled to the body 144b and is movable forward and backward relative to the body 144b. A plurality of index arms 144c are provided. The index arms 144c are individually driven. The index arms 144c are stacked one above another with a spacing gap therebetween along the third direction 16. Some of the index arms 144c may be used to transfer the substrates W from the process module 200 to the carriers 130, and the other index arms 144c may be used to transfer the substrates W from the carriers 130 to the process module 200. Accordingly, particles generated from the substrates W that are to be treated may be prevented from adhering to the treated substrates W in a process in which the index robot 144 transfers the substrates W between the carriers 130 and the process module 200.

The transfer chamber 240 transfers the substrates W between the buffer unit 220 and the process chambers 300 and between the process chambers 300. A guide rail 242 and a main robot 244 are provided in the transfer chamber 240. The guide rail 242 is disposed such that the lengthwise direction thereof is parallel to the first direction 12. The main robot 244 is installed on the guide rail 242 and rectilinearly moves on the guide rail 242 along the first direction 12. The main robot 244 has a base 244a, a body 244b, and a main arm 244c. The base 244a is installed so as to be movable along the guide rail 242. The body 244b is coupled to the base 244a. The body 244b is movable on the base 244a along the third direction 16. Furthermore, the body 244b is rotatable on the base 244a. The main arm 244c is coupled to the body 244b and is movable forward and backward relative to the body 244b. A plurality of main arms 244c are provided. The main arms 244c are individually driven. The main arms 244c are stacked one above another with a spacing gap therebetween along the third direction 16.

Each of the process chambers 300 performs a liquid treatment process on the substrate W. The process chambers 300 may have different structures depending on the types of processes performed. In contrast, the process chambers 300 may have the same structure. Selectively, the process chambers 300 may be divided into a plurality of groups. The process chambers 300 belonging to the same group may have the same structure, and the process chambers 300 belonging to different groups may have different structures.

In this embodiment, it will be exemplified that a substrate treating process is a film removal process of removing a thin film T on an edge region of a substrate W. However, the substrate treating process may be a different type of process other than the film removal process.

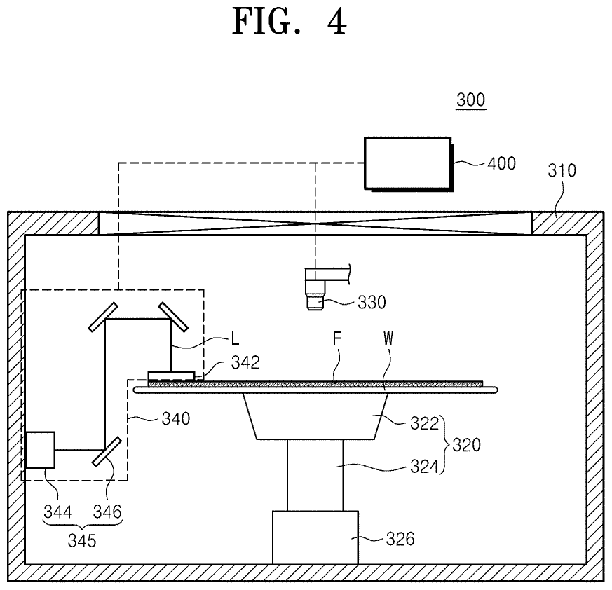

FIG. 4 is a schematic sectional view illustrating the process chamber of FIG. 3. Referring to FIG. 4, the process chamber 300 includes a housing 310, a support unit 320, a liquid dispensing unit 330, a laser irradiation unit 340, and a controller 400.

The housing 310 has a treatment space therein. The support unit 320 supports the substrate W in the treatment space. The support unit 320 supports and rotates the substrate W during the substrate treating process. The support unit 320 has a support plate 322 and a rotary shaft 324. The support plate 322 has a substantially circular plate shape. An upper surface of the support plate 322 may have a larger diameter than a lower surface of the support plate 322. A side surface of the support plate 322 that connects the upper surface and the lower surface of the support plate 322 may be downwardly inclined toward the central axis of the support plate 322. The upper surface of the support plate 322 serves as a seating surface on which the substrate W is seated. The seating surface has a smaller area than the substrate W. According to an embodiment, the diameter of the seating surface may be smaller than the radius of the substrate W. The seating surface supports a central region of the substrate W.

The rotary shaft 324 has a cylindrical shape, the lengthwise direction of which is oriented in an up-down direction. The rotary shaft 324 is coupled to the lower surface of the support plate 322. An actuator 326 transmits torque to the rotary shaft 324. The rotary shaft 324 is rotatable about the central axis thereof by the torque transmitted from the actuator 326. The support plate 322 is rotatable together with the rotary shaft 324. The actuator 326 may adjust the rotational speed of the rotary shaft 324 to adjust the rotational speed of the substrate W. For example, the actuator 326 may be a motor. Without being limited thereto, however, the actuator 326 may include various well-known devices for applying torque to the rotary shaft 324.

The liquid dispensing unit 330 dispenses a liquid onto the substrate W. The liquid may be an alkaline chemical. Alternatively, the liquid may be water.

The laser irradiation unit 340 may irradiate a laser L to the substrate W supported on the support unit 320. The laser irradiation unit 340 irradiates the laser L to the edge region of the substrate W. The laser L irradiated from the laser irradiation unit 340 may remove a film on the edge region of the substrate W.

When the laser L is irradiated, a plate 342 may be provided on a liquid film F so as to be brought into contact with the surface of the liquid dispensed onto the substrate W by the liquid dispensing unit 330. The plate 342 may be moved between a liquid contact position and a standby position by an actuator (not illustrated). The liquid contact position is a position in which the plate 342 is brought into contact with the surface of the liquid on an irradiation path of the laser L when the laser L is irradiated to the substrate W. The standby position is a position in which the plate 342 does not interfere with the substrate W when the substrate W is placed on the support plate 322 or when the substrate W is raised off the support plate 322.

The plate 342 may be moved between the liquid contact position and the standby position by rotary motion or linear motion. The plate 342 is formed of a material through which the laser L transmits. For example, the material of the plate 342 may be quartz. The laser L irradiated from a laser irradiation member 345 transmits through the plate 342 and is irradiated to the edge region of the substrate W.

The laser irradiation member 345 includes a light source 344 and an optical-path changing member. The optical-path changing member includes one or more mirrors 346. The optical-path changing member changes the path of light irradiated from the light source 344 such that the light is irradiated to the substrate W after transmitting through the plate 342. The mirrors 346 may be moved to desired positions through a mirror actuator (not illustrated).

The controller 400 controls the liquid dispensing unit 330 and the laser irradiation unit 340. For example, the controller 400 may control when and where the laser L is irradiated to the substrate W and when the liquid is dispensed onto the substrate W. According to an embodiment, an irradiation position of the laser L irradiated to the substrate W may be changed by moving the positions of the mirrors 346.

An upper surface of the plate 342 may be parallel to the substrate W placed on the support unit 320. At this time, the laser irradiation member 345 may irradiate the laser L in a direction perpendicular to the substrate W placed on the support unit 320.

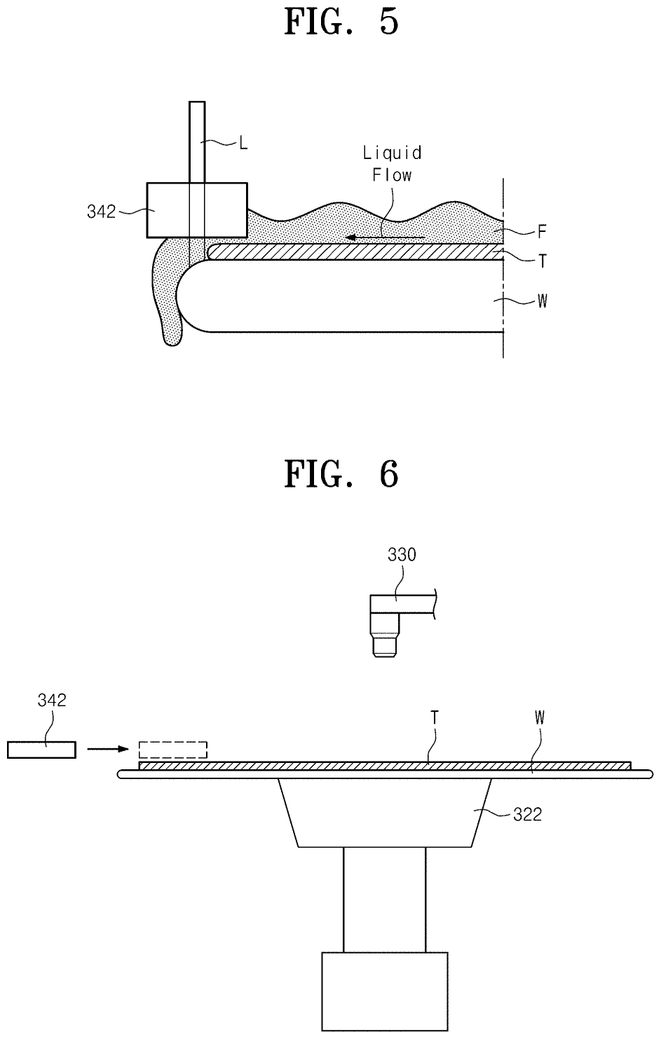

Hereinafter, a substrate treating method of the inventive concept will be described with reference to FIGS. 5 to 10. In an embodiment, the substrate treating process is a process of removing the thin film T formed on the substrate W. Referring to FIG. 5, first, the substrate W is placed on the support unit 320. Next, the plate 342 in the standby position is moved to the liquid contact position above the thin film T formed on the substrate W.

Referring to FIG. 6, the liquid dispensing unit 330 dispenses the liquid onto the substrate W after the plate 342 is moved. After the plate 342 is moved to the liquid contact position, the laser irradiation unit 340 irradiates the laser L to the substrate W, and a process of removing the thin film T starts. The controller 400 may control the liquid dispensing unit 330 and the laser irradiation unit 340 to perform the substrate treating method that will be described below.

In the substrate treating method of the inventive concept, the liquid is dispensed onto the substrate W to form the liquid film F on the substrate W, and thereafter the substrate W is treated by the laser L irradiated to the substrate W, in which the plate 342 is brought into contact with the liquid film F formed on the substrate W, and the laser L transmits through the plate 342 and treats the substrate W.

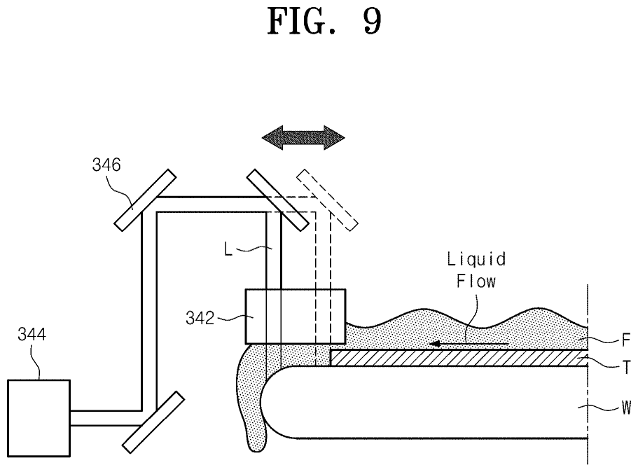

FIG. 8 illustrates a state in which the laser L is irradiated to the substrate W by the laser irradiation unit 340 after the plate 342 is moved to the liquid contact position. FIG. 9 illustrates a state in which the laser L irradiated to the plate 342 is moved according to an embodiment of the inventive concept. Referring to FIG. 9, the positions of the mirrors 346 may be changed such that the irradiation position of the laser L is changed. As the laser L is irradiated to the substrate W, the thin film T formed on the substrate W is removed.

At this time, the position of the plate 342 may be fixed, and the laser irradiation member 345 may be moved such that the irradiation position of the laser L irradiated to the plate 342 is changed along the radial direction of the substrate W placed on the support unit 320.

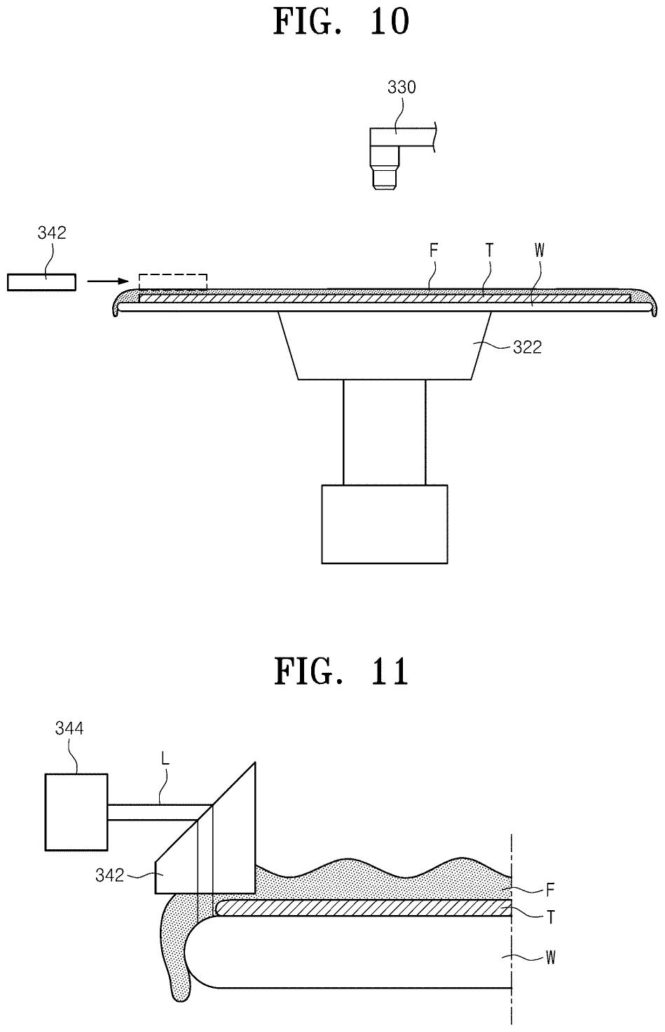

Hereinabove, it has been described that the plate 342 in the standby position is moved to the liquid contact position above the thin film T formed on the substrate W. However, as illustrated in FIG. 10, the plate 342 in the standby position may be moved to the liquid contact position after the liquid dispensing unit 330 dispenses the liquid onto the thin film T formed on the substrate W.

In the case of removing the thin film T on the substrate W by irradiating the laser L to the substrate W, particles (P) are generated in the process in which the thin film T is removed.

In the inventive concept, the liquid is dispensed onto the substrate W, and the laser L is irradiated in the state the plate 342 is brought into contact with the liquid. In a case where ablation is performed after the liquid is applied to the substrate W as in the inventive concept, the particles P separated from the substrate W are captured in the liquid. The particles P in the liquid are floated in the liquid without adhering to the substrate W because in the liquid, adhesion of the particles P to the substrate W is weaker than in the air.

That is, according to the inventive concept, when the liquid under the plate 342 is moved, the particles P may be removed together with the liquid along the flow of the liquid. Accordingly, in a case of collecting dust in a dry environment, the particles P separated from the substrate W may be prevented from adhering to the substrate W again and contaminating the substrate W again.

Furthermore, when the laser L is irradiated to the substrate W through the plate 342 after the plate 342 is located on the liquid applied to the substrate W, the upper surface of the liquid is maintained to be parallel to the substrate W, which is supported on the support unit 320, due to the plate 342, and the liquid has a uniform thickness of “d”.

Accordingly, the inventive concept may solve the problem that, in a case where the plate 342 is not provided and therefore the thickness of the liquid is not maintained to be uniform, the upper surface of the liquid is uneven so that the laser L is not irradiated to a desired position and an unnecessary position is ablated.

Hereinabove, it has been described that the plate 342 is provided to be flat. However, the upper surface of the plate 342 may be diversely provided as follows.

Referring to FIG. 11, the upper surface of the plate 342 may be upwardly inclined in a direction toward the center of the substrate W placed on the support unit 320. As the upper surface of the plate 342 is upwardly inclined in the direction toward the center of the substrate W placed on the support unit 320, the position where the laser L is irradiated to the substrate W may be changed without being limited to the top side of the substrate W. In a case where the upper surface of the plate 342 is inclined at an angle of 45 degrees as illustrated in FIG. 11, the laser L may be irradiated in a direction parallel to a side of the substrate W.

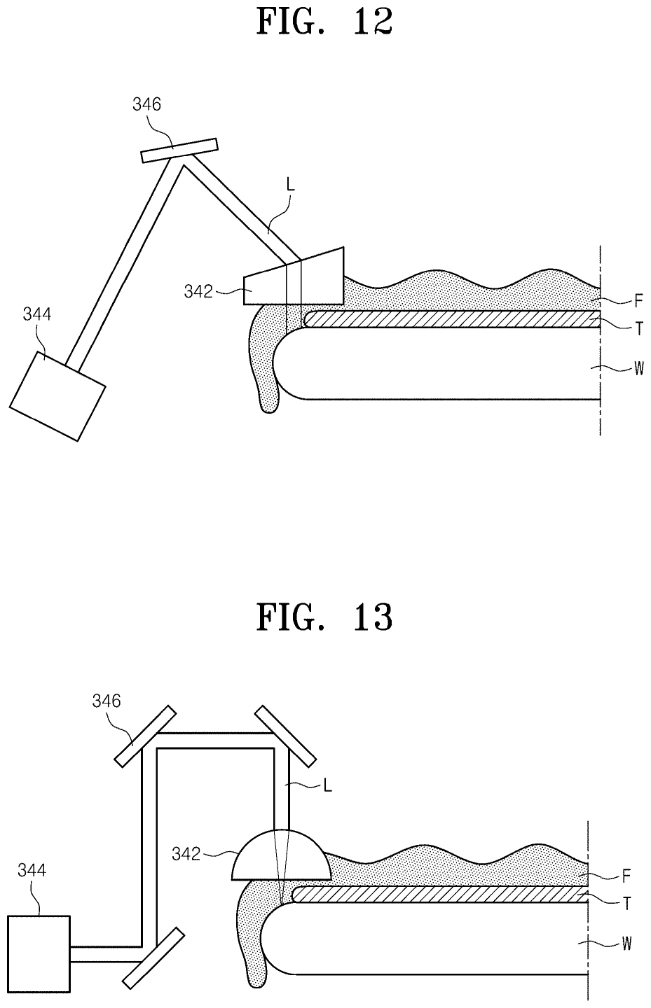

Referring to FIG. 12, the upper surface of the plate 342 may be upwardly inclined in the direction toward the center of the substrate W placed on the support unit 320, and the angle of the upper surface of the plate 342 may be smaller than the angle in FIG. 11. At this time, the laser irradiation member 345 may irradiate the laser L to the inclined surface of the plate 342 from outside the substrate W.

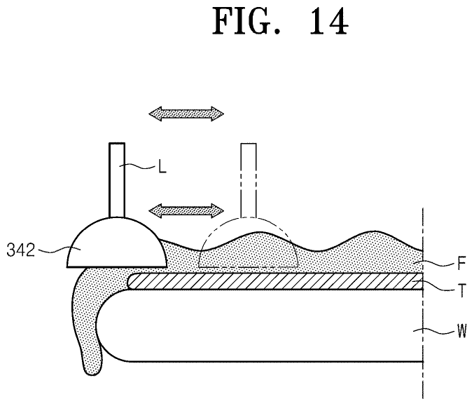

Referring to FIG. 13, the plate 342 may have a convex upper surface and may concentrate the laser L on a specific position on the substrate W. At this time, as in FIG. 8, the laser irradiation member 345 may irradiate the laser L in the direction perpendicular to the substrate W placed on the support unit 320.

The plate 342 may have a rounded concave upper surface other than the convex upper surface. In a case where the range in which the laser L is irradiated to the substrate W is set to be larger than the existing irradiation range of the laser L, the upper surface of the plate 342 may be set to be concave, and in a case where the range in which the laser L is irradiated to the substrate W is set to be smaller than the existing irradiation range of the laser L, the upper surface of the plate 342 may be set to be convex as in FIG. 13.

Referring to FIG. 14, the irradiation position of the laser L may be changed along the radial direction of the substrate W, and the position of the plate 342, together with the irradiation position of the laser L, may be changed such that the laser L is irradiated to the same point on the plate 342.

The laser irradiation member 345 may further include a plate actuator (not illustrated) that moves the plate 342. The plate actuator may change the position of the plate 342 to correspond to the irradiation position of the laser L such that the laser L is irradiated to a specific position of the plate 342 while the irradiation position of the laser L is changed.

The method for treating the substrate W may be a method for removing the thin film T on the substrate W by irradiating a plurality of lasers L to the edge region of the substrate W. The thin film T on the substrate W may be a film formed by a deposition process. For example, the film on the substrate W may be TiN, SiN, tungsten, oxide, or the like.

However, the substrate treating method according to the embodiment of the inventive concept is not limited to the method for removing the film and may be similarly applied to various treatment methods for treating the substrate W by irradiating the laser L to the substrate W.

Without being limited to treating the edge region of the substrate W, the substrate treating method according to the embodiment of the inventive concept may be a method for treating the entire surface of the substrate W. For example, the substrate treating method may be applied to various processes such as a process of cutting a substrate, a process of removing a film, and the like.

As described above, according to the embodiments of the inventive concept, a film on a substrate may be efficiently removed by using a laser.

Furthermore, according to the embodiments of the inventive concept, a laser may be accurately irradiated to a specific region on a substrate when the substrate is treated by irradiating the laser to the substrate.

Moreover, according to the embodiments of the inventive concept, a laser may be concentrated on a specific region on a substrate when the substrate is treated by irradiating the laser to the substrate.

In addition, according to the embodiments of the inventive concept, the width of a space for treating a substrate may be reduced in an up-down direction when the substrate is treated by irradiating a laser to the substrate.

Effects of the inventive concept are not limited to the above-described effects, and any other effects not mentioned herein may be clearly understood from this specification and the accompanying drawings by those skilled in the art to which the inventive concept pertains.

The above description exemplifies the inventive concept. Furthermore, the above-mentioned contents describe exemplary embodiments of the inventive concept, and the inventive concept may be used in various other combinations, changes, and environments. That is, variations or modifications can be made to the inventive concept without departing from the scope of the inventive concept that is disclosed in the specification, the equivalent scope to the written disclosures, and/or the technical or knowledge range of those skilled in the art. The written embodiments describe the best state for implementing the technical spirit of the inventive concept, and various changes required in specific applications and purposes of the inventive concept can be made. Accordingly, the detailed description of the inventive concept is not intended to restrict the inventive concept in the disclosed embodiment state. In addition, it should be construed that the attached claims include other embodiments.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

1. An apparatus for treating a substrate, the apparatus comprising:
a housing having a treatment space therein;
a support unit configured to support the substrate in the housing;
a liquid dispensing unit configured to dispense a liquid onto the substrate supported on the support unit;
a laser irradiation unit configured to irradiate a laser to an edge region of the substrate; and
a controller configured to control the liquid dispensing unit and the laser irradiation unit,
wherein the laser irradiation unit includes:
a plate provided on the liquid so as to be brought into contact with a surface of the liquid dispensed onto the substrate; and
a laser irradiation member configured to irradiate the laser to the edge region of the substrate, which is supported on the support unit, through the plate.

2. The apparatus of claim 1, wherein an upper surface of the plate is parallel to the substrate placed on the support unit.

3. The apparatus of claim 1, wherein an upper surface of the plate is rounded.

4. The apparatus of claim 3, wherein the upper surface of the plate is convex.

5. The apparatus of claim 1, wherein an upper surface of the plate is inclined along a radial direction of the substrate placed on the support unit.

6. The apparatus of claim 5, wherein the upper surface of the plate is upwardly inclined in a direction toward the center of the substrate placed on the support unit.

7. The apparatus of claim 2, wherein the laser irradiation member irradiates the laser in a direction perpendicular to the substrate placed on the support unit.

8. The apparatus of claim 6, wherein on a side of the substrate placed on the support unit, the laser irradiation member irradiates the laser to the plate in a direction parallel to the substrate.

9. The apparatus of claim 1, wherein the laser irradiation member includes:
a light source; and
an optical-path changing member including a mirror configured to change a path of light irradiated by the light source, and
wherein the optical-path changing member further includes a mirror actuator configured to move the mirror.

10. The apparatus of claim 9, wherein the controller controls the mirror actuator to change a position of the mirror such that a position in which the laser is irradiated to the substrate is changed while the laser is irradiated.

11. The apparatus of claim 4, wherein the laser irradiation member includes a plate actuator configured to move the plate, and
wherein the controller controls the plate actuator to change a position of the plate to correspond to an irradiation position of the laser such that the laser is irradiated to a specific position of the plate while the irradiation position of the laser is changed.

12. The apparatus of claim 2, wherein the controller controls the laser irradiation member such that an irradiation position of the laser in which the laser is irradiated to the plate is changed along a radial direction of the substrate placed on the support unit.

13. The apparatus of claim 5, wherein the controller controls the laser irradiation member such that an irradiation position of the laser in which the laser is irradiated to the plate is changed along an up-down direction.

14. The apparatus of claim 1, wherein the controller controls the liquid dispensing unit and the laser irradiation unit such that the liquid is dispensed and the laser is irradiated in a state in which the plate is brought into contact with the liquid.

15. An apparatus for treating a substrate, the apparatus comprising:
a housing having a treatment space therein;
a support unit configured to support the substrate in the housing;
a liquid dispensing unit configured to dispense a liquid onto the substrate supported on the support unit; and
a laser irradiation unit configured to irradiate a laser to the substrate,
wherein the laser irradiation unit includes:
a plate provided on the liquid so as to be brought into contact with a surface of the liquid dispensed onto the substrate; and
a laser irradiation member configured to irradiate the laser to the substrate, which is supported on the support unit, through the plate.

16. The apparatus of claim 15, wherein an upper surface of the plate is parallel to the substrate placed on the support unit.

17. The apparatus of claim 15, wherein an upper surface of the plate is convex.

18. The apparatus of claim 15, wherein an upper surface of the plate is upwardly inclined in a direction toward the center of the substrate placed on the support unit.

19. The apparatus of claim 15, wherein the laser irradiation member includes:
a light source; and
an optical-path changing member including a mirror configured to change a path of light irradiated by the light source, and
wherein the optical-path changing member further includes a mirror actuator configured to move the mirror.

20. The apparatus of claim 19, further comprising:
a controller configured to control the liquid dispensing unit and the laser irradiation unit,
wherein the controller controls the mirror actuator to change a position of the mirror such that a position in which the laser is irradiated to the substrate is changed while the laser is irradiated.

21.-29. (canceled)
